(19) United States
(12) Patent Application Publication
(10) Pub. No.: US 2026/0005096 A1
(43) Pub. Date: Jan. 1, 2026

(54) HEAT SPREADERS THAT INCLUDE THERMAL DISSIPATION REGIONS COMPRISING DIAMOND

(71) Applicant: Intel Corporation, Santa Clara, CA (US)

(72) Inventors: Je-Young CHANG, Tempe, AZ (US); Aastha UPPAL, Chandler, AZ (US); Aravindha ANTONISWAMY, Chandler, AZ (US)

(21) Appl. No.: 18/758,073

(22) Filed: Jun. 28, 2024

(51) Int. Cl. H01L 23/373; H01L 21/48; H01L 23/00; H01L 23/31; H01L 23/367; H01L 25/065

(52) U.S. Cl. CPC H01L 23/3732; H01L 23/367; H01L 24/32; H01L 21/4803; H01L 23/3107; H01L 25/0655; H01L 2224/32245

(57) ABSTRACT

Assemblies comprising semiconductor devices, packages, and heat spreaders are provided. The heat spreaders comprise heat dissipation regions comprising diamond. The diamond can be, for example, a solid diamond plate or a composite comprising diamond particles. Methods for manufacturing assemblies comprising heat spreaders that include heat dissipation regions comprising diamond are also provided.

### FIELD

Descriptions are generally related to semiconductor packaging assemblies, and more particular descriptions are related to heat spreaders having regions comprising diamond for semiconductor device packages.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

The increasing demand for higher computing power and efficiency in smaller form factors drives the need for new packaging architectures. Three dimensional (3D) or 2.5 dimensional (2.5D) integration of semiconductor devices in packages can be an option to increase transistor device density through vertically or horizontally integrating two or more dies on package substrates. A dense highspeed interface having shorter interconnect lengths can be used between 3D (stacked) or 2.5D integrated semiconductor dies. Three dimensional and 2.5D semiconductor device packaging can enable smaller form factors for devices used in a variety of market segments. Despite promising electrical and form factor benefits for 3D and 2.5D packaging assemblies, cooling 3D and 2.5D packaged semiconductor devices remains a challenge. Overheating can negatively impact the performance and lifespan of a semiconductor device in a package assembly.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIGS. 1A-1G provide semiconductor device assemblies that include heat spreaders having thermal dissipation regions.

FIGS. 2A-2B show views of heat spreaders having thermal dissipation regions.

FIGS. 3A-3C illustrate some examples of semiconductor device package arrangements for multiple semiconductor devices.

FIG. 4 illustrates an additional semiconductor device assembly that includes a heat spreader having a thermal dissipation region.

FIG. 5 shows a method for manufacturing assemblies comprising a heat spreader having one or more thermal dissipation regions.

FIG. 6 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, thermally, physically, magnetically, optically, and/or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine and/or physical operations. Physical operations can be performed by semiconductor processing and/or manufacturing equipment, that can include computer operate aspects of semiconductor manufacturing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing equipment that is able to perform physical operations such as, for example, pick-and-place operations, solder ball dispensing, lithography, material deposition (for example, chemical vapor deposition, atomic layer deposition, physical vapor deposition, electrodeposition, and/or sputtering), chemical mechanical polishing, surface cleaning, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed, in part, from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conducting features can be interlayer dielectric (ILD) features. In general, low-K dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more semiconductor chips, in which the semiconductor chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, examples of solid amorphous glass substrate cores can be considered to have a rectangular prism volume. The rectangular prism volume can contain vias that have been filled with one or more different materials. A material in a via can be a conducting metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example. However, assembling an interconnect bridge having TBVs into substrate package can present yield challenges and architectures which simplify the assembly process of interconnect bridges having TBVs into a package substrate cavity are important.

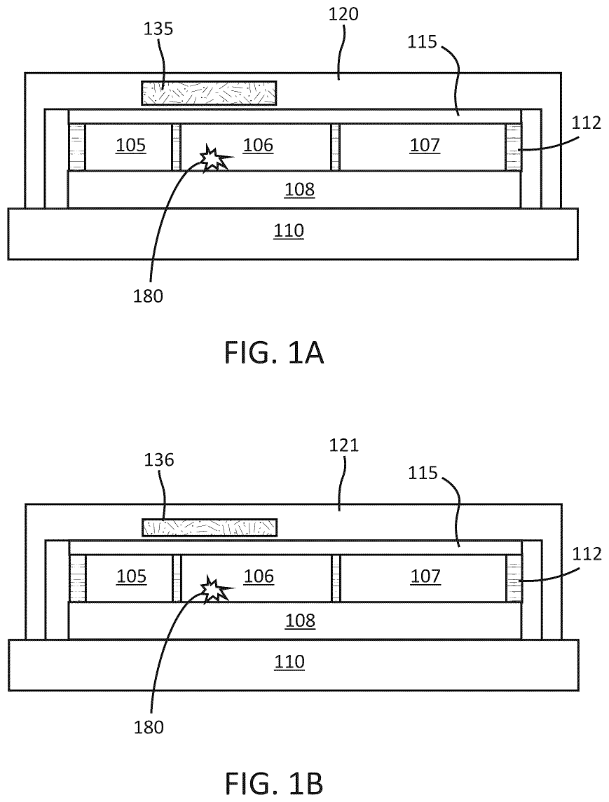

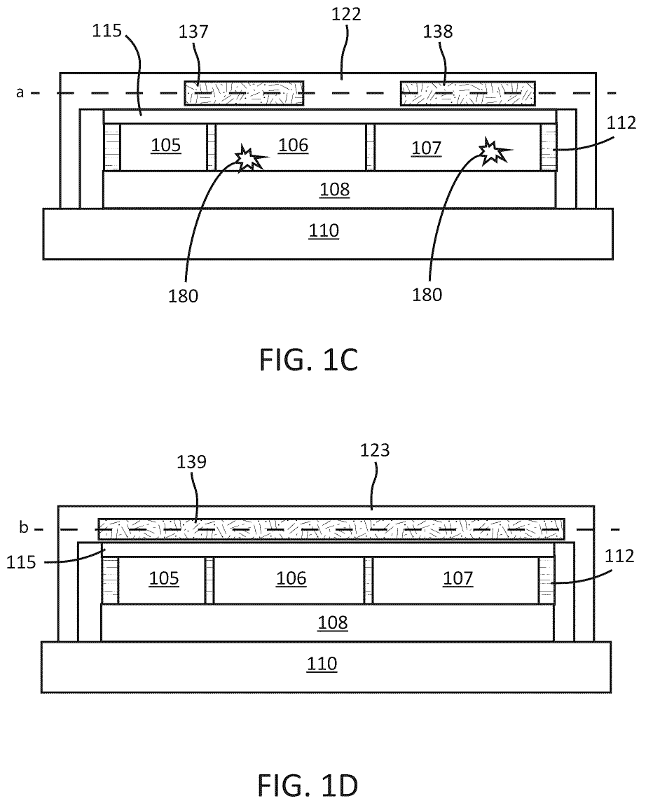

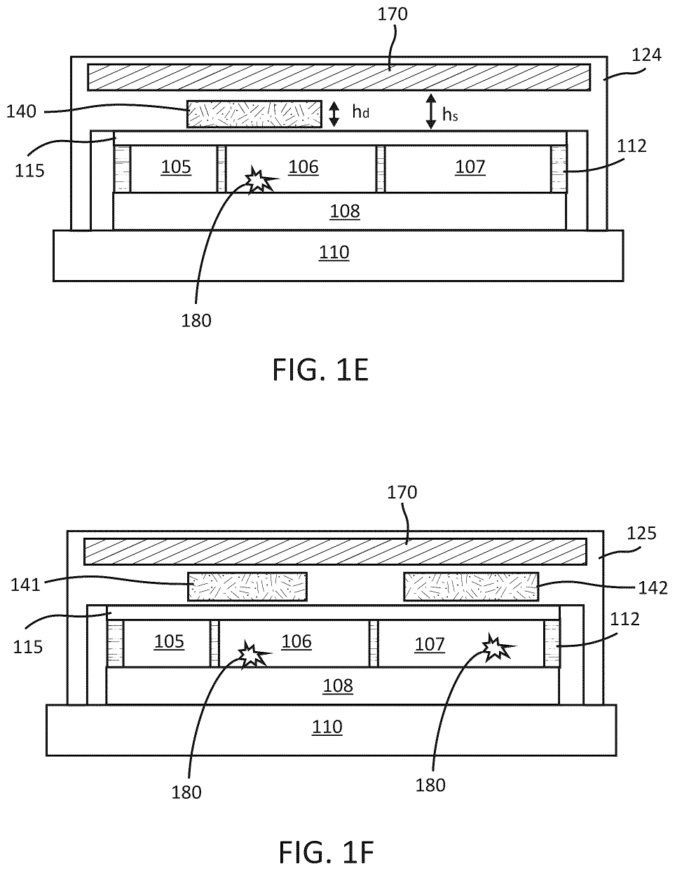

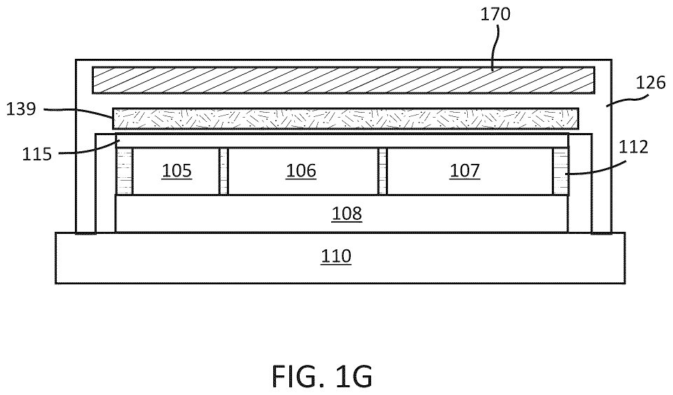

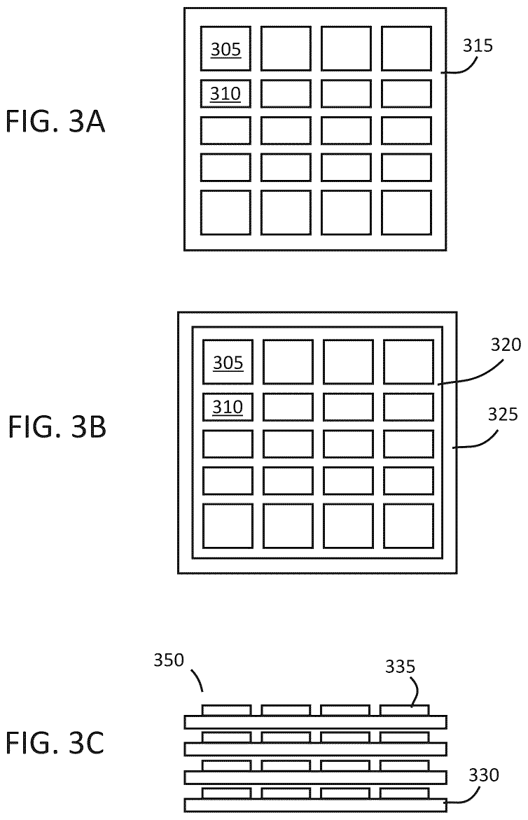

FIGS. 1A-1G illustrate semiconductor device assemblies that include a heat spreader comprising a thermal dissipation region. The semiconductor device assemblies include semiconductor devices 105, 106, 107, and 108. Semiconductor devices 105, 106, 107, and 108 are shown as a 3D assembly in which semiconductor devices 105, 106, and 107 are stacked on and electrically coupled to semiconductor device 108. In some examples, semiconductor device 108 can be an interposer comprising electrical signal conduits between coupled dies. Interposers can be comprised of, for example, silicon and/or organic materials. FIGS. 3A-3C provide additional examples of semiconductor device arrangements. Other numbers, numbers of types, and arrangements of semiconductor devices are also possible and semiconductor device assemblies possible are not limited to the ones illustrated. For example, semiconductor device assemblies can include one semiconductor device or can include multiple devices as shown in the example semiconductor device layouts of FIGS. 1A-1G. Semiconductor devices 105, 106, and 107 are electrically coupled to semiconductor device 108 through semiconductor device interconnect regions (not shown) located between semiconductor devices 105, 106, and 107, that can comprise, for example, bumps, pins, pads, rods, or electrically conductive regions having other shapes. The semiconductor device interconnect regions (not shown) can be for power delivery and communication. Semiconductor device 108 is electrically coupled to package substrate 110 through additional interconnect regions (not shown) located between semiconductor device 108 and package substrate 110, that can comprise, for example, bumps, pins, pads, rods, or electrically conductive regions having other shapes. These interconnect regions (not shown) that couple a semiconductor device 108 to a package substrate can be first level interconnects (FLIs). Package substrate 110 can be any of the types of package substrates described herein. A dielectric encapsulation material 112 can encapsulate or partially encapsulate one or more of the semiconductor devices 105, 106, 107, and 108 and be comprised of, for example, an epoxy material. A thermal interface material 115 (TIM) can be located between semiconductor devices 105, 106, and 107 and a heat spreader 120, 121, 122, 123, 124, 125, or 126. Thermal interface materials 115 can be materials that aid in thermally coupling (i.e., heat is transferred) a heat spreader 120, 121, 122, 123, 124, 125, or 126 with the semiconductor devices 105, 106, 107, and 108. Typically, TIMs 115 are deformable and thermally conductive materials, and a variety of materials are possible, such as, for example, metals, metallic composites, pastes, gels, greases, epoxies, silicone-based materials, and adhesives. TIMS can comprise, metallic particles. Other materials are possible for TIMs 115.

Heat spreaders 120, 121, 122, 123, 124, 125, and 126 can also be called, for example, integrated heat spreaders (IHSs). Heat spreaders 120, 121, 122, 123, 124, 125, or 126 can be comprised of in part, for example, one or more regions of a thermally conductive material, such as a metallic material, such as, copper, gold, palladium, aluminum, silver, or a combination thereof. Heat spreaders 120, 121, 122, 123, 124, 125 and 126 comprise one or more thermal dissipation regions 135, 136, 137, 138, 139 140, 141, and/or 142. Thermal dissipation regions 135 136, 137, 138, 139 140, 141, and 142 can be a material that is comprised of diamond (a material comprising carbon atoms). The one or more regions of thermally conductive material (metallic material) can be, for example, at least 10%, at least 20%, at least 30%, at least 40%, at least 50%, at least 60%, at least 70% or at least 80% of the total volume of the heat spreader 120, 121, 122, 123, 124, 125, or 126. The material that is comprised of diamond can be a solid plate that is at least 70%, 90%, at least 95%, at least 98% diamond, or at least 99% diamond (a solid form of carbon having carbon atoms arranged in diamond cubic arrangement) by weight. A diamond plate can have, for example, a single crystalline or a poly-crystalline structure. Alternately, the material comprised of diamond can be a composite comprising diamond particles. A composite of diamond particles can have, for example, a percent composition of 5% or more, 10% or more, 20% or more, 50% or more, or 75% or more of carbon atoms by weight. A composite of diamond particles can have, for example, a percent composition of between 5% and 80%, between 10% and 80%, or between 20% and 90%, of carbon atoms by weight. A composite can also be 40-70% or 50-60% by volume diamond particles. The diamond particles can be particles that are between 30 μm and 800 μm in one or more dimensions. The diamond particles can be, for example, a composite with a metal (an alloy), such as for example, copper, silver, gold, aluminum, tungsten, zinc, or a combination of one or more of the foregoing. The diamond particle alloy can also include diamond particles having a coating. A diamond particle coating can be comprised of, for example, palladium, tin, nickel, or a combination of one or more of the foregoing. Carbide-forming elements such as tungsten, titanium, chromium, or boron can be coated on the diamond particles or alternatively alloyed into a Cu matrix. A composite of diamond particles can exhibit a coefficient of thermal expansion (CTE) of between 2 C⁻¹ and 11 C⁻¹.

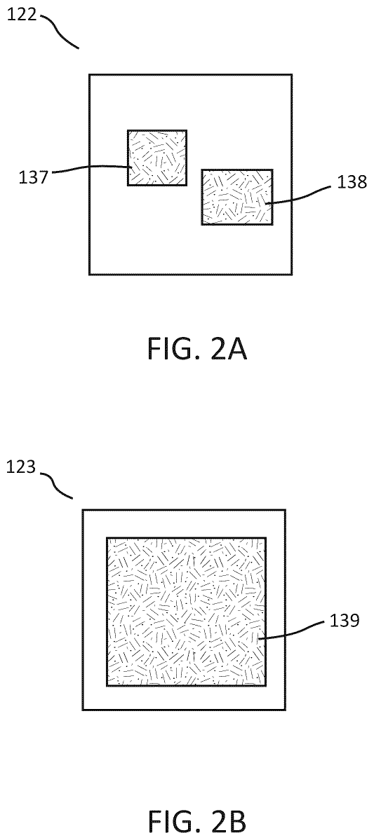

The thermal dissipation regions 135, 136, 137, 138, 139, 140, 141, and 142 can be embedded in, on one or more surfaces of, or protruding from one or more surfaces of a heat spreader 120, 121, 122, 123, 124, 125, or 126. The thermal dissipation regions 135, 136, 137, 138, and 139 can be, for example, as thick as, slightly thicker than, between 50% and 95% as thick as, less than 85% as thick as, less than 75% as thick as, or less than 50% as thick as a heat spreader 120, 121, 122, or 123. In FIG. 1A, the heat spreader 120 comprises a thermal dissipation region 135 that is between 50% and 95% as thick as the heat spreader 120 and in FIG. 1B, the heat spreader 121 comprises a thermal dissipation region 136 that is less than 75% as thick as the heat spreader 121. In FIGS. 1A-1C, the thermal dissipation regions 135, 136, 137, and 138 are located proximate to hot spots 180. Hot spots 180 are regions of semiconductor devices 106 and 107 (FIG. 1C for 107) where, in operation, the semiconductor device can heat up disproportionately relative to other regions of the device. In general, a semiconductor device can have zero, one, two, or three or more hot spots 180. One or more thermal dissipation regions 135, 136, 137, 138, 139, 140, 141, and/or 142 can provide increased heat transfer capabilities as compared to a heat spreader that does not comprise one or more thermal dissipation regions 135 136, 137, 138, 139, 140, 141, and/or 142. In FIGS. 1D and 1G, an example the thermal dissipation region 139 spans a surface of semiconductor devices 105, 106, and 107 in at least one direction. FIGS. 2A and 2B show exemplary footprints (additional dimensions) for the thermal dissipation regions 137, 138, and 139. Although rectangular shapes having 6 sides are shown for thermal dissipation regions 135 136, 137, 138, 139, 140, 141, and 142, other shapes are possible, such as for example, spherical, ellipsoid, a shape having more than 6 sides, a shape having less than 6 sides, and/or cylindrical.

In FIGS. 1E-1G, the heat spreaders 124, 125, and 126 comprise a liquid cooling region 170. The liquid cooling region 170 can be comprised of, for example, microchannels, micro-pin fins, or hybrid structures. The liquid cooling region 170 can also be a vapor chamber. The liquid cooling region 170 can also comprise a liquid that is able to provide cooling through physical state transitions (e.g., liquid-vapor transitions). The liquid cooling region 170 that has microchannels, micro-pin fins, or hybrid structures can serve as a heat exchanger through which liquid can be pumped and heat transferred from the heat spreaders 124, 125, and 126 to the liquid. The liquid cooling region 170 that is a vapor chamber is an enclosed region that contains a fluid and can include structures, such as wicking regions. Heat spreaders 124, 125, and 126 additionally comprise one or more thermal dissipation regions 140, 141, 142, and 139. The thermal dissipation regions 140, 141, 142, and 139 can have a height, “h_{d}” (shown in FIG. 1E) relative to the height between a surface of the heat exchanger and the liquid cooling region 170, “hₛ” (shown in FIG. 1E) that is between 90 and 100%, between 60% and 90%, between 30% and 60%, between 5% and 30%, or between 5% and 90% of the height of hₛ.

FIGS. 2A-2B show views of heat spreaders 122 and 123. FIGS. 2A-2B are planar views of the cut-through lines labeled “a” in FIG. 1C and “b” in FIG. 1D (shown as dashed lines). Lines “a” and “b” are in the plane that is being viewed. In FIG. 2B thermal dissipation region 139 is shown spanning a surface of semiconductor devices 105, 106, and 107 in two directions.

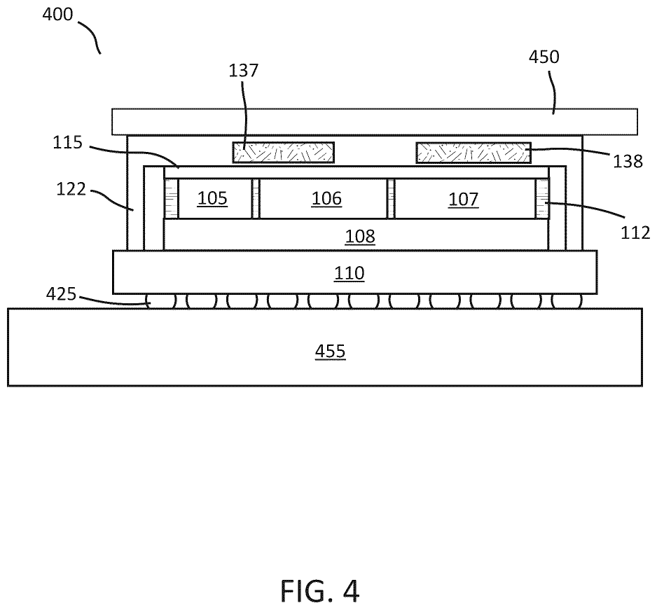

FIGS. 3A-3C provide examples of multi-chip arrangements in packages that can be used in the assemblies of FIGS. 1A-1G and 4. Other numbers of semiconductor devices, types of semiconductor devices, and arrangements are possible. In FIG. 3A, semiconductor devices 305 and 310 are operably coupled to a package substrate 315. Package substrate 315 can include, for example, interconnect bridges (such as, for example, those described herein) to electrically couple semiconductor devices 305 and 310 to each other and/or to a circuit board (not shown). In FIG. 3B, semiconductor devices 305 and 310 are operably coupled to an interposer 320 that can provide electrical connections to and between the semiconductor devices 305 and 310. The interposer 320 can be comprised of, for example, silicon and/or an organic dielectric material. The interposer 320 is operably coupled to a package substrate 325. The package substrate 325 can be, for example, a package substrate as described herein. In FIG. 3C, a stacked assembly 350 is provided comprising semiconductor devices 335 and interposers 330. The stacked assembly 350 can be, for example, a 3D or 3DHI (3D with heterogeneous integration of semiconductor devices). Interposers 330 can be the same or different and semiconductor devices 335 can be the same or different on each interposer 330 shown.

FIG. 4 provides a further semiconductor device assembly 400 comprising semiconductor devices and a heat spreader comprising thermal dissipation regions. Although the assembly from FIG. 1C is used in FIG. 4, any of the assemblies of FIGS. 1A-1G could be used in the assembly of FIG. 4. Where the numbering of a part is the same in FIG. 4 as it is in FIGS. 1A-1G, the descriptions for that part are useful for the same-numbered part in FIG. 4. In FIG. 4, the semiconductor device assembly 400 comprises a circuit board 455 that is operably coupled to package substrate 110 though conductive regions 425. The circuit board 455 can be, for example, a mother board, a logic board, a board, a mainboard, a system board, and/or a printed circuit board. The circuit board 455 can comprise wiring that connects semiconductor devise 105, 106, 107, and/or 108 to other computing, memory, input output (IO), and/or logic devices and to a power source. The power source can be, in some examples, a battery. The circuit board can comprise transformers that transfer power or electricity to devices. Conductive regions 425 can be solder regions, pins, pins that fit into a socket (not shown) in circuit board 455, rods, pads, or other conductive structures. Optionally, the semiconductor device assembly 400 includes a thermal plate 450 that is capable of removing heat from heat spreader 122. Thermal plate 450 can be comprised, for example, of a metal, such as, for example, copper, gold, palladium, aluminum, or a combination thereof.

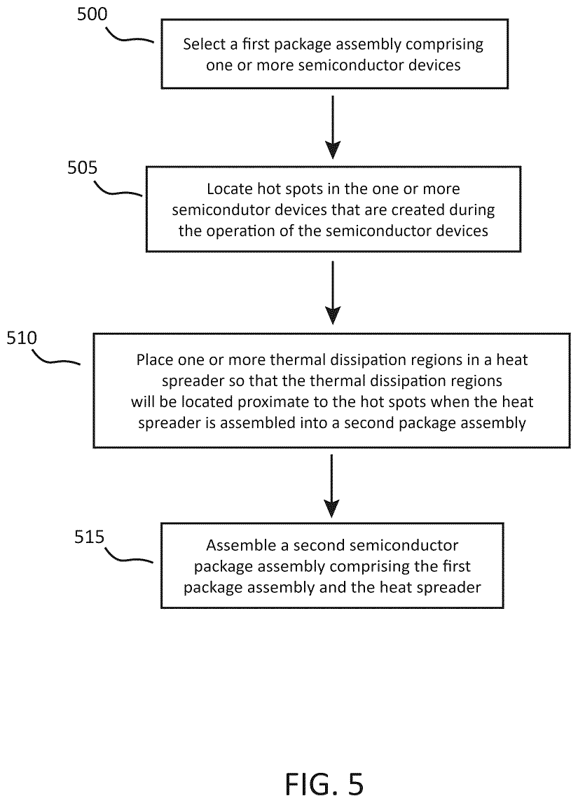

FIG. 5 describes a method for manufacturing a semiconductor device assembly having a heat spreader that comprises one or more thermal dissipation regions. The method described in FIG. 5 can be used, for example, to manufacture the assemblies shown in FIGS. 1A-1G and 4. A first package assembly comprising one or more semiconductor devices coupled to a package substrate is selected 500. The one or more semiconductor devices of the first package assembly are tested to determine locations for hot spots that are formed during semiconductor device operation 505. The hot spots can be determined, for example, by the logic unit floorplan design of each silicon chip, in which the heat generation of all the logic units is analyzed collectively under operating conditions to determine the hot spots. A heat spreader comprising thermal dissipation regions is manufactured 510. The thermal dissipation regions can be located proximate to (e.g., so that the length of the shortest line that can be drawn between the hot spot and the surface of the thermal dissipation region is minimized) one or more hot spot locations on one or more semiconductor devices, after an assembly is created comprising the one or more semiconductor devices and the heat spreader 510. The first assembly comprising the one or more semiconductor devices on the package substrate and the heat spreader comprising thermal dissipation regions are assembled to create a second assembly 515. The second assembly can be manufactured, for example, by dispensing a thermal interface material on a surface of the one or more semiconductor devices and using a pick and place robot to place the heat spreader on the first assembly.

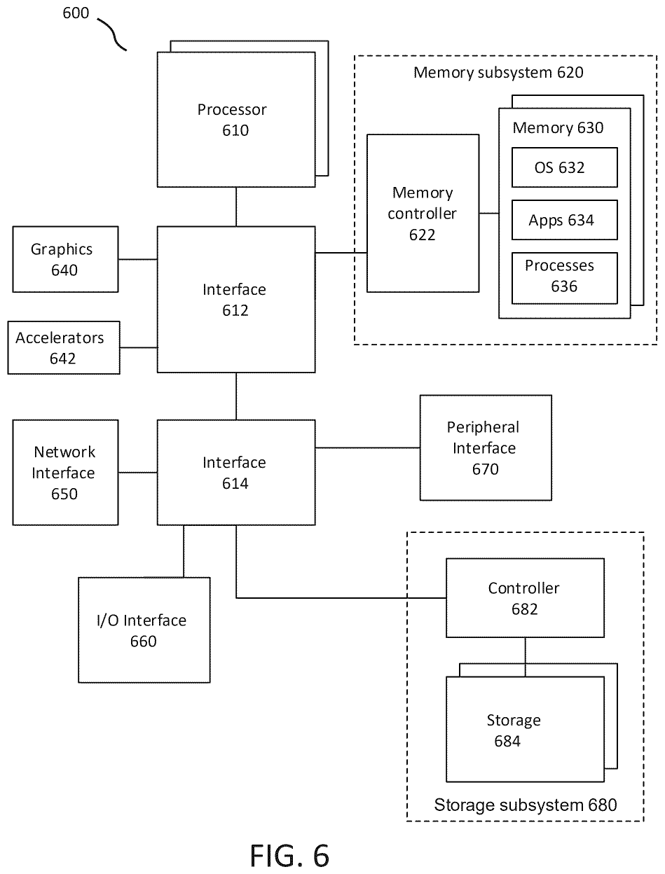

In FIGS. 1A-1G, 3A-3C, 4, and 5 the semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package and/or onto one interposer. The semiconductor chips can be any of the chips, for example, described herein with respect to FIG. 6. The semiconductor chip packages described herein generally can be part of various larger package structures and configurations and the foregoing examples are not meant to limit the types of assemblies that are possible.

FIG. 6 depicts an example computing system which can be used in conjunction with the method of FIG. 5 to run one or more units of testing and fabrication equipment. The computing system can be a system used for running equipment in a semiconductor fabrication plant. For example, instructions for operating testing, analysis, and/or pick and place robots, or for performing one or more aspects of the process described in FIG. 5 can be stored and/or run on the computing system. A computing system 600 can include more, different, or fewer features than the ones described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or circuit board, printed circuit board, mainboard, system board, or logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 can be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Examples of systems may be implemented in various types of computing, smart phones, tablets, personal computers, and networking equipment, such as switches, routers, racks, and blade servers such as those employed in a data center and/or server farm environment.

### EXAMPLES

An assembly can comprise: a package substrate; a semiconductor die electrically coupled to the package substrate; and a heat spreader wherein the heat spreader comprises a metallic region and a second region that comprises greater than 5% carbon atoms by weight, wherein the metallic region is at least 20% of the total volume of the heat spreader, and wherein the heat spreader is attached to the package substrate. The second region can be a solid diamond plate. The second region can be a composite comprising a metal and diamond particles. The second region can be a composite comprising diamond particles and copper, silver, gold, aluminum, tungsten, zinc, or a combination thereof. The heat spreader can be comprised of copper and the second region is an alloy comprising diamond and copper. The second region can be a composite that comprises between 5% and 80% carbon atoms by weight. The second region can be a composite comprising a metal and diamond particles and wherein the diamond particles have a coating and the coating is comprised of palladium, tin, nickel, or a combination thereof.

An assembly can comprise: a circuit board comprising a transformer; a package substrate wherein the package substrate is electrically coupled to the circuit board; a semiconductor die electrically coupled to the package substrate wherein the transformer is capable of delivering power to the semiconductor die through the package substrate; and a heat spreader wherein the heat spreader comprises a metallic region and a second region that comprises greater than 5% carbon atoms by weight, wherein the metallic region is at least 20% of the total volume of the heat spreader, and wherein the heat spreader is attached to the package substrate. The second region can be a solid diamond plate. The second region can be a diamond composite comprising diamond particles having a dimension between 30 and 800 μm. The second region can be a composite comprising diamond particles and copper, silver, gold, aluminum, tungsten, zinc, or a combination thereof. The metallic region can be comprised of copper and the second region is an alloy of diamond and copper. The second region can be a composite that comprises between 5% and 80% carbon atoms by weight. The second region is proximate to a hot spot that is produced in the semiconductor die when the semiconductor die is in operation.

A method for manufacturing an assembly can comprise: determining one or more locations where heat is emitted from an operating semiconductor die disproportionately from other locations in the semiconductor die; producing a heat spreader comprising a metallic region and a second region comprising diamond within the metallic region; and placing the heat spreader on a package substrate wherein the package substrate comprises the semiconductor die. The second region can comprise a solid diamond plate. The second region can be a composite comprising diamond particles. The second region can be a diamond alloy that comprises 5% or more by volume of diamond particles. The second region can be proximate to a location of the one or more locations where heat is emitted from an operating semiconductor die disproportionately. The second region can be a composite comprising diamond particles and copper, silver, gold, aluminum, tungsten, zinc, or a combination thereof

Besides what is described herein, various modifications can be made to what is disclosed and implementations without departing from their scope. Therefore, the drawings and examples herein should be construed in an illustrative, and not a restrictive sense.

What is claimed is:

1. An assembly comprising:
a package substrate;
a semiconductor die electrically coupled to the package substrate; and
a heat spreader wherein the heat spreader comprises a metallic region and a second region that comprises greater than 5% carbon atoms by weight, wherein the metallic region is at least 20% of the total volume of the heat spreader, and wherein the heat spreader is attached to the package substrate.

2. The assembly of claim 1 wherein the second region is a solid diamond plate.

3. The assembly of claim 1 wherein the second region is a composite comprising a metal and diamond particles.

4. The assembly of claim 1 wherein the second region is a composite comprising diamond particles and copper, silver, gold, aluminum, tungsten, zinc, or a combination thereof.

5. The assembly of claim 1 wherein the metallic region is comprised of copper and the second region is an alloy comprising diamond and copper.

6. The assembly of claim 1 wherein the second region is a composite that comprises between 5% and 80% carbon atoms by weight.

7. The assembly of claim 1 wherein the second region is a composite comprising a metal and diamond particles and wherein the diamond particles have a coating and the coating is comprised of palladium, tin, nickel, or a combination thereof.

8. An assembly comprising:
a circuit board comprising a transformer;
a package substrate wherein the package substrate is electrically coupled to the circuit board;
a semiconductor die electrically coupled to the package substrate wherein the transformer is capable of delivering power to the semiconductor die through the package substrate; and
a heat spreader wherein the heat spreader comprises a metallic region and a second region that comprises greater than 5% carbon atoms by weight, wherein the metallic region is at least 20% of the total volume of the heat spreader, and wherein the heat spreader is attached to the package substrate.

9. The assembly of claim 8, wherein the second region is a solid diamond plate.

10. The assembly of claim 8 wherein the second region is a diamond composite comprising diamond particles having a dimension between 30 and 800 μm.

11. The assembly of claim 8 wherein the second region is a composite comprising diamond particles and copper, silver, gold, aluminum, tungsten, zinc, or a combination thereof.

12. The assembly of claim 8 wherein the metallic region is comprised of copper and the second region is an alloy of diamond and copper.

13. The assembly of claim 8 wherein the second region is a composite that comprises between 5% and 80% carbon atoms by weight.

14. The assembly of claim 8 wherein the second region is proximate to a hot spot that is produced in the semiconductor die when the semiconductor die is in operation.

15. A method for manufacturing an assembly comprising:
determine one or more locations where heat is emitted from an operating semiconductor die disproportionately from other locations in the semiconductor die;
producing a heat spreader comprising a metallic region and a second region comprising diamond within the metallic region; and
place the heat spreader on a package substrate wherein the package substrate comprises the semiconductor die.

16. The method of claim 15, wherein the region comprises a solid diamond plate.

17. The method of claim 15, wherein the region is a composite comprising diamond particles.

18. The method of claim 15, wherein the region is a diamond alloy that comprises 5% or more by volume of diamond particles.

19. The method of claim 15, wherein the region is proximate to a location of the one or more locations where heat is emitted from an operating semiconductor die disproportionately.

20. The method of claim 15, wherein the region is a composite comprising diamond particles and copper, silver, gold, aluminum, tungsten, zinc, or a combination thereof.
